(19) United States
(12) Patent Application Publication
(10) Pub. No.: US 2025/0364224 A1
(43) Pub. Date: Nov. 27, 2025

(54) PLASMA PROCESSING APPARATUS AND PLASMA PROCESSING METHOD

(71) Applicant: Tokyo Electron Limited, Tokyo (JP)

(72) Inventors: Hwajun JUNG, Hwaseong-si (KR); Mitsunori OHATA, Miyagi (JP); Yuki HOSAKA, Miyagi (JP); Takayuki KAWAMURA, Miyagi (JP)

(73) Assignee: Tokyo Electron Limited, Tokyo (JP)

(21) Appl. No.: 19/290,448

(22) Filed: Aug. 5, 2025

Related U.S. Application Data
(63) Continuation of application No. PCT/JP2024/003245, filed on Feb. 1, 2024.

(30) Foreign Application Priority Data
Feb. 13, 2023 (JP) 2023-020302

(51) Int. Cl. H01J 37/32

(52) U.S. Cl. CPC H01J 37/32633; H01J 37/32816; H01J 37/32082

(57) ABSTRACT

A plasma processing apparatus includes: a plasma processing chamber, a substrate support disposed in the plasma processing chamber, an annular baffle plate disposed to surround the substrate support, the annular baffle plate having openings, a first annular plate disposed below the annular baffle plate with an inner end fixed to a sidewall of the substrate support, a movable structure disposed below the first annular plate, the movable structure including a cylindrical wall vertically disposed along a sidewall of the plasma processing chamber, a gap being formed between the cylindrical wall and the sidewall of the plasma processing chamber, and a second annular plate disposed on an upper end of an inner wall of the cylindrical wall, the second annular plate having an annular overlapping portion vertically overlapping a part of the first annular plate, and an actuator for vertically moving the movable structure.

### CROSS-REFERENCE TO RELATED APPLICATIONS

This application is a bypass continuation application of international application No. PCT/JP2024/003245 having an international filing date of Feb. 1, 2024 and designating the United States, the international application being based upon and claiming the benefit of priority from Japanese Patent Application No. 2023-020302, filed on Feb. 13, 2023, the entire contents of each are incorporated herein by reference.

### TECHNICAL FIELD

The present disclosure relates to a plasma processing apparatus and a plasma processing method.

### BACKGROUND

PTL 1 discloses a substrate processing apparatus including a processing chamber in which plasma processing is performed on a substrate, an exhaust chamber communicating with the processing chamber, an exhaust plate having a plurality of first vent holes and separating the processing chamber and the exhaust chamber from each other, and an exhaust adjusting plate disposed in the exhaust chamber. According to the substrate processing apparatus described in PTL 1, the exhaust adjusting plate has a plurality of second vent holes and is configured to be contactable with and separable from the exhaust plate in parallel to each other.

### CITATION LIST

### Patent Documents

PTL 1: JP2012-15451A

### SUMMARY

A technique according to the present disclosure provides a plasma processing apparatus capable of controlling an internal pressure of a processing chamber in a short time.

One aspect of the present disclosure is a plasma processing apparatus. The plasma processing apparatus includes: a plasma processing chamber, a substrate support disposed in the plasma processing chamber, an annular baffle plate disposed to surround the substrate support, the annular baffle plate having openings, a first annular plate disposed below the annular baffle plate with an inner end fixed to a sidewall of the substrate support, a movable structure disposed below the first annular plate, the movable structure including a cylindrical wall vertically disposed along a sidewall of the plasma processing chamber, a gap being formed between the cylindrical wall and the sidewall of the plasma processing chamber, and a second annular plate disposed on an upper end of an inner wall of the cylindrical wall, the second annular plate having an annular overlapping portion vertically overlapping a part of the first annular plate, and an actuator configured to vertically move the movable structure.

According to the present disclosure, a plasma processing apparatus capable of controlling an internal pressure of a processing chamber in a short time can be provided.

### BRIEF DESCRIPTION OF DRAWINGS

FIG. 1 is a diagram schematically illustrating a configuration of a plasma processing system;

FIG. 2 is a vertical sectional view schematically illustrating an example of a configuration of a plasma processing apparatus;

FIG. 3 is a major part enlarged view illustrating a configuration example of a major part of an exhaust system;

FIG. 4 is a perspective cross-sectional view illustrating an outline of a configuration example of a second pressure adjusting mechanism;

FIG. 5 is a plan view illustrating a disposition example of the second pressure adjusting mechanism;

FIG. 6 is a diagram illustrating an example of a relationship between a spacing in the second pressure adjusting mechanism and an internal pressure of a plasma processing chamber;

FIG. 7 is a major part enlarged view illustrating a modification of the second pressure adjusting mechanism;

FIG. 8 is a perspective cross-sectional view illustrating a modification of the second pressure adjusting mechanism;

FIG. 9 is a major part enlarged view illustrating a modification of the second pressure adjusting mechanism;

FIG. 10 is a major part enlarged view illustrating a modification of the second pressure adjusting mechanism; and

FIG. 11 is a diagram illustrating a result of Example of the technique according to the present disclosure.

### DETAILED DESCRIPTION

In a process of manufacturing a semiconductor device, a processing gas is supplied to a semiconductor substrate (hereinafter, simply referred to as “substrate”), so that the substrate is subjected to various types of plasma processing such as etching processing, film forming processing, and diffusion processing. The plasma processing is performed in a plasma processing apparatus including a processing chamber, the inside of which may be controlled to a vacuum environment. In the plasma processing apparatus, it is important to precisely control the internal pressure of the processing chamber in order to appropriately perform the plasma processing on the substrate.

PTL 1 described above discloses a substrate processing apparatus (plasma processing apparatus) including an exhaust plate configured to separate a processing chamber and an exhaust chamber from each other, and an exhaust adjusting plate configured to be contactable with and separable from the exhaust plate in order to precisely control the internal pressure of the processing chamber. The exhaust plate and the exhaust adjusting plate are formed respectively with a plurality of vent holes perforated in a thickness direction. Then, the substrate processing apparatus described in PTL 1 is configured to enable fine pressure adjustment at a relatively low pressure or at a relatively high pressure by adjusting the position of the exhaust adjusting plate with respect to the exhaust plate.

Meanwhile, in a recent process of manufacturing a semiconductor device, it is required to adjust an internal pressure of a processing chamber in a short time in response to a demand for miniaturization of patterns formed on a substrate surface. However, in the processing chamber in which plasma processing is performed, it may be difficult to adjust the pressure in a short time since it requires, for example, a plasma gas or a large-capacity power source. Particularly, when the plasma processing apparatus has an inductively coupled plasma (ICP) generator, the capacity of the processing chamber is generally increased. Therefore, it has been great concern to adjust the internal pressure of the processing chamber in a short time.

The technique according to the present disclosure has been made in view of the above circumstances and provides a plasma processing apparatus capable of controlling an internal pressure of a processing chamber in a short time. Hereinafter, a plasma processing system including a plasma processing apparatus according to the present embodiment and a plasma processing method according to the embodiment will be described with reference to the drawings. The same reference numerals will be given to elements having substantially the same functional configurations throughout the specification and the drawings, and redundant description thereof will be omitted.

### <Configuration of Plasma Processing System>

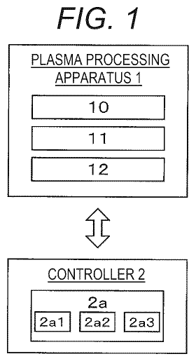

First, a plasma processing system according to an embodiment will be described. FIG. 1 is a diagram illustrating an outline of a configuration of the plasma processing system.

In one embodiment, a plasma processing system includes a plasma processing apparatus 1 and a controller 2 as illustrated in FIG. 1. The plasma processing apparatus 1 includes a plasma processing chamber 10, a substrate support 11, and a plasma generator 12.

The plasma processing chamber 10 has a plasma processing space. The plasma processing chamber 10 has at least one gas supply port via which at least one processing gas is supplied into the plasma processing space, and at least one gas exhaust port via which the gas is exhausted from the plasma processing space. The gas supply port is connected to a gas supply 20, which will be described later, and the gas exhaust port is connected to an exhaust system 40, which will be described later. The substrate support 11 is disposed in the plasma processing space and has a substrate support surface for supporting the substrate.

The plasma generator 12 is configured to generate plasma from at least one processing gas supplied into the plasma processing space. The plasma formed in the plasma processing space may be capacitively coupled plasma (CCP), inductively coupled plasma (ICP), electron-cyclotron-resonance plasma (ECR plasma), helicon wave plasma (HWP), surface wave plasma (SWP), or the like. Further, various types of plasma generators, including an alternating current (AC) plasma generator and a direct current (DC) plasma generator, may be used. In one embodiment, an AC signal (AC power) used by the AC plasma generator has a frequency in a range of 100 kHz to 10 GHz. Accordingly, the AC signal includes a radio frequency (RF) signal and a microwave signal. In one embodiment, the RF signal has a frequency in a range of 100 kHz to 150 MHz.

The controller 2 processes computer-executable instructions for instructing the plasma processing apparatus 1 to execute various steps described herein below. The controller 2 may be configured to control elements of the plasma processing apparatus 1 to execute the various steps described herein below. In one embodiment, part or all of the controller 2 may be in the plasma processing apparatus 1. The controller 2 may include a processor 2a1, a storage 2a2, and a communication interface 2a3. The controller 2 is implemented, for example, by a computer 2a. The processor 2al may be configured to read a program from the storage 2a2 and perform various control operations by executing the read program. The program may be stored in advance in the storage 2a2, or may be acquired via a medium when necessary. The acquired program is stored in the storage 2a2, read from the storage 2a2 by the processor 2al, and executed thereby. The medium may be any of various recording media readable by the computer 2a, or may be a communication line connected to the communication interface 2a3. The processor 2al may be a central processing unit (CPU). The storage 2a2 may include a random access memory (RAM), a read only memory (ROM), a hard disk drive (HDD), a solid state drive (SSD), or a combination thereof. The communication interface 2a3 may communicate with the plasma processing apparatus 1 via a communication line such as a local area network (LAN). Further, the storage medium may be temporary or non-temporary medium. The functionality of the elements disclosed herein may be implemented using circuitry or processing circuitry which includes general purpose processors, special purpose processors, integrated circuits, ASICs (“Application Specific Integrated Circuits”), FPGAs (“Field-Programmable Gate Arrays”), conventional circuitry and/or combinations thereof which are programmed, using one or more programs stored in one or more memories, or otherwise configured to perform the disclosed functionality. Processors and controllers are considered processing circuitry or circuitry as they include transistors and other circuitry therein. In the disclosure, the circuitry, units, or means are hardware that carry out or are programmed to perform the recited functionality. The hardware may be any hardware disclosed herein which is programmed or configured to carry out the recited functionality. There is a memory that stores a computer program which includes computer instructions. These computer instructions provide the logic and routines that enable the hardware (e.g., processing circuitry or circuitry) to perform the method disclosed herein. This computer program can be implemented in known formats as a computer-readable storage medium, a computer program product, a memory device, a record medium such as a CD-ROM or DVD, and/or the memory of a FPGA or ASIC.

### <Configuration of Plasma Processing Apparatus>

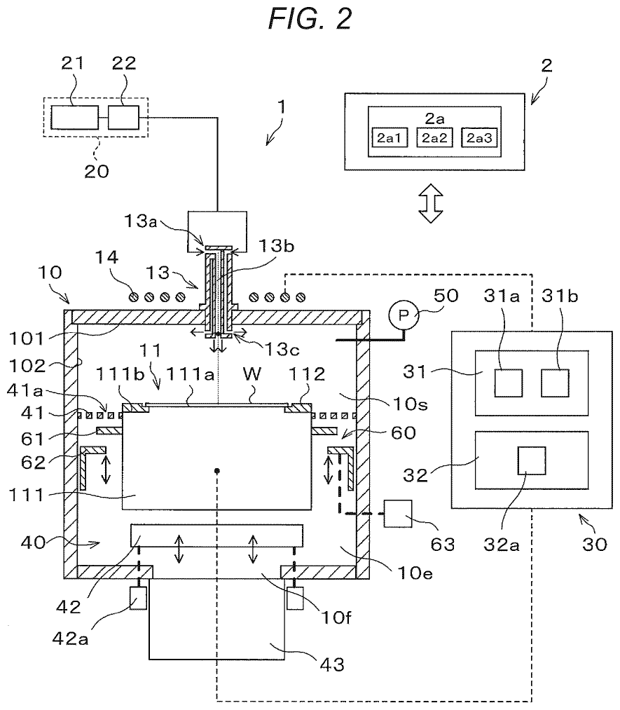

Hereinafter, a configuration example of an inductively coupled plasma processing apparatus (ICP) as an example of the plasma processing apparatus 1 will be described. FIG. 2 is a vertical sectional view illustrating an outline of a configuration of the plasma processing apparatus 1.

The inductively coupled plasma processing apparatus 1 includes the plasma processing chamber 10, the gas supply 20, a power source 30, the exhaust system 40, and a pressure detector 50. The plasma processing chamber 10 includes a dielectric window 101. Further, the plasma processing apparatus 1 includes the substrate support 11, a gas introduction unit, and an antenna 14. The substrate support 11 is disposed in the plasma processing chamber 10. The antenna 14 is disposed over or above the plasma processing chamber 10 (that is, over or above the dielectric window 101). The plasma processing chamber 10 has a plasma processing space 10s defined by the dielectric window 101, a sidewall 102 of the plasma processing chamber 10, and the substrate support 11. The plasma processing chamber 10 has at least one gas supply port for supplying at least one processing gas into the plasma processing space 10s, and at least one gas exhaust port for exhausting the gas from the plasma processing space 10s. The volume of the plasma processing chamber 10 is, for example, 50 L or more.

The substrate support 11 includes a main body 111 and a ring assembly 112. The main body 111 has a central region 111a, which supports a substrate W, and an annular region 111b, which supports the ring assembly 112. A wafer is an example of the substrate W. The annular region 111b of the main body 111 surrounds the central region 111a of the main body 111 in a plan view. The substrate W is disposed on the central region 111a, and the ring assembly 112 is disposed on the annular region 111b to surround the substrate W on the central region 111a. Accordingly, the central region 111a is also called a substrate support surface that supports the substrate W, and the annular region 111b is also called a ring support surface that supports the ring assembly 112.

In one embodiment, the main body 111 includes a base (not illustrated) and an electrostatic chuck (not illustrated). The base includes a conductive member. The conductive member of the base may function as a bias electrode. The electrostatic chuck is disposed on the base. The electrostatic chuck includes an electrostatic electrode (not illustrated). The electrostatic chuck has the central region 111a. In one embodiment, the electrostatic chuck also has the annular region 111b. An annular electrostatic chuck and other members that surround the electrostatic chuck such as an annular insulating member may have the annular region 111b. In this case, the ring assembly 112 may be disposed on the annular electrostatic chuck or the annular insulating member, or may be disposed on both the electrostatic chuck and the annular insulating member. At least one RF/DC electrode coupled to an RF power source 31 and/or a DC power source 32, which will be described later, may be disposed in the electrostatic chuck. In this case, at least one RF/DC electrode functions as the bias electrode. The conductive member of the base and at least one RF/DC electrode may function as a plurality of bias electrodes. Further, the electrostatic electrode may function as the bias electrode. Accordingly, the substrate support 11 includes at least one bias electrode.

The ring assembly 112 includes one or more annular members. In one embodiment, the one or more annular members include one or more edge rings and at least one cover ring. The edge ring is formed of a conductive material or an insulating material, and the cover ring is formed of an insulating material.

Although not illustrated, the substrate support 11 may include a temperature control module configured to adjust at least one of the electrostatic chuck, the ring assembly 112, and the substrate W to a target temperature. The temperature control module may include a heater, a heat transfer medium, a flow path, or a combination thereof. A heat transfer fluid, such as brine or gas, flows through the flow path. In one embodiment, the flow path is formed in the base and one or more heaters are disposed in the electrostatic chuck. The substrate support 11 may include a heat transfer gas supply configured to supply a heat transfer gas between a rear surface of the substrate W and the substrate support surface.

The gas introduction unit is configured to introduce at least one processing gas from the gas supply 20 into the plasma processing space 10s. In one embodiment, the gas introduction unit includes a center gas injector (CGI) 13. The center gas injector 13 is disposed above the substrate support 11 and attached to a center opening formed in the dielectric window 101. The center gas injector 13 has at least one gas supply port 13a, at least one gas flow path 13b, and at least one gas introduction port 13c. The processing gas supplied to the gas supply port 13a passes through the gas flow path 13b and is introduced into the plasma processing space 10s from the gas introduction port 13c. The gas introduction unit may include one or more side gas injectors (SGI) attached to one or more openings formed in the sidewall 102, in addition to or instead of the center gas injector 13.

The gas supply 20 may include at least one gas source 21 and at least one flow rate controller 22. In one embodiment, the gas supply 20 is configured to supply at least one processing gas from the respective corresponding gas sources 21 to the gas introduction unit through the respective corresponding flow rate controllers 22. Each flow rate controller 22 may include, for example, a mass flow controller or a pressure-controlled flow rate controller. Further, the gas supply 20 may include at least one flow rate modulation device that modulates or pulses the flow rate of at least one processing gas.

The power source 30 includes the RF power source 31 coupled to the plasma processing chamber 10 via at least one impedance matching circuit. The RF power source 31 is configured to supply at least one RF signal (RF power) to the at least one bias electrode and the antenna 14. Accordingly, the plasma is formed from at least one processing gas supplied into the plasma processing space 10s. Accordingly, the RF power source 31 may function as at least a part of the plasma generator 12. Supplying the bias RF signal to at least one bias electrode can generate a bias potential in the substrate W to attract ions in the formed plasma to the substrate W.

In one embodiment, the RF power source 31 includes a first RF generator 31a and a second RF generator 31b. The first RF generator 31a is configured to be coupled to the antenna 14 through at least one impedance matching circuit so as to generate the source RF signal (source RF power) for plasma generation. In one embodiment, the source RF signal has a frequency within a range from 10 MHz to 150 MHz. In one embodiment, the first RF generator 31a may be configured to generate a plurality of source RF signals having different frequencies. The generated one or more source RF signals are supplied to the antenna 14.

The second RF generator 31b is coupled to at least one bias electrode via the at least one impedance matching circuit and configured to generate the bias RF signal (bias RF power). A frequency of the bias RF signal may be the same as or different from a frequency of the source RF signal. In one embodiment, the bias RF signal has a frequency lower than the frequency of the source RF signal. In one embodiment, the bias RF signal has a frequency within a range from 100 kHz to 60 MHz. In one embodiment, the second RF generator 31b may be configured to generate a plurality of bias RF signals having different frequencies. The generated one or more bias RF signals are supplied to at least one bias electrode. In various embodiments, at least one of the source RF signal and the bias RF signal may be pulsed.

The power source 30 may include the DC power source 32 coupled to the plasma processing chamber 10. The DC power source 32 includes a bias DC generator 32a. In one embodiment, the bias DC generator 32a is connected to at least one bias electrode and configured to generate a bias DC signal. The generated bias DC signal is applied to at least one bias electrode.

In various embodiments, the bias DC signal may be pulsed. In this case, a sequence of voltage pulses is applied to at least one bias electrode. The voltage pulse may have a pulse waveform of a rectangle, a trapezoid, a triangle or a combination thereof. In one embodiment, a waveform generator for generating the sequence of voltage pulses from the DC signal is connected between the bias DC generator 32a and at least one bias electrode. Accordingly, the bias DC generator 32a and the waveform generator configure a voltage pulse generator. The voltage pulse may have a positive polarity or a negative polarity. Further, the sequence of the voltage pulses may include one or more positive voltage pulses and one or more negative voltage pulses in one cycle. The bias DC generator 32a may be provided in addition to the RF power source 31, or may be provided instead of the second RF generator 31b.

The antenna 14 includes one or more coils. In one embodiment, the antenna 14 may include an outer coil and an inner coil that are coaxially disposed. In this case, the RF power source 31 may be connected to both the outer coil and the inner coil, or may be connected to any one of the outer coil and the inner coil. In the former case, the same RF generator may be connected to both the outer coil and the inner coil, or separate RF generators may be connected to the outer coil and the inner coil, respectively.

The exhaust system 40 exhausts and decompresses the inside of the plasma processing chamber 10 (plasma processing space 10s) via an exhaust path 10e formed around the substrate support 11 in a plan view and a gas exhaust port 10f formed in the bottom surface of the plasma processing chamber 10. The exhaust system 40 includes an annular baffle plate 41 that separates the plasma processing space 10s and the exhaust path 10e from each other, a first pressure adjusting mechanism 42 that opens and closes the gas exhaust port 10f by an operation of a driving mechanism 42a, and an exhaust mechanism 43 that exhausts the inside of the plasma processing space 10s via the first pressure adjusting mechanism 42. In the present embodiment, a second pressure adjusting mechanism 60 that adjusts the internal pressure of the plasma processing space 10s in a short time is disposed downstream of the annular baffle plate 41 in the exhaust path 10e. The second pressure adjusting mechanism 60 includes an upper plate 61, a movable structure 62, and an actuator 63. A detailed configuration of the exhaust system 40 including the second pressure adjusting mechanism 60 will be described later.

The pressure detector 50 measures the internal pressure of the plasma processing chamber 10 (plasma processing space 10s) during plasma processing. The type of the pressure detector 50 is not particularly limited, and may be freely determined as long as the internal pressure of the plasma processing chamber 10 can be measured.

### <Configuration of Exhaust System>

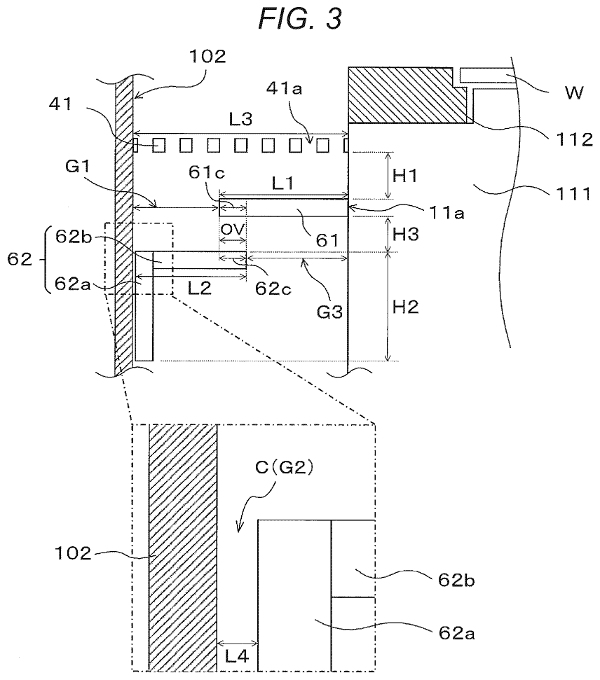

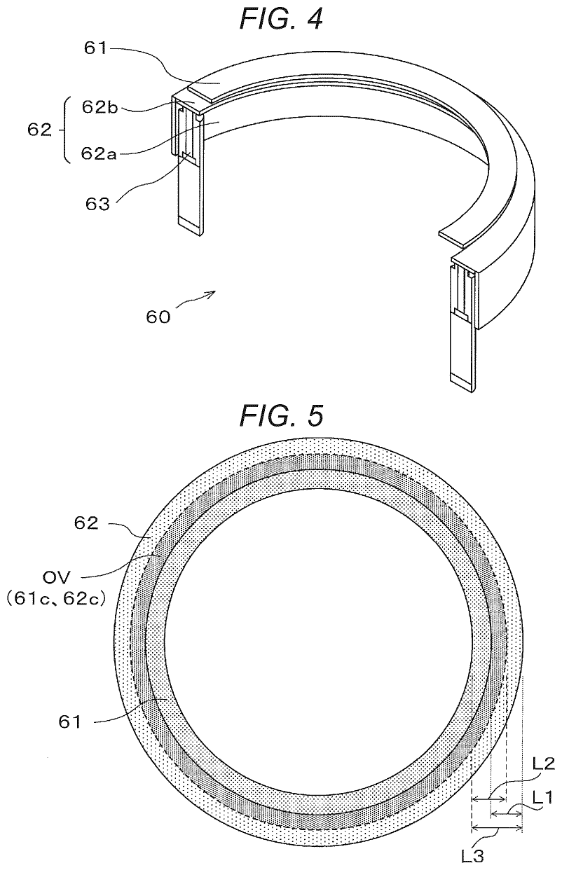

Next, an example of a detailed configuration of the above-described exhaust system 40 will be described. FIG. 3 is a major part enlarged view illustrating a major part of the exhaust system 40 in an enlarged scale. FIG. 4 is a perspective cross-sectional view schematically illustrating the second pressure adjusting mechanism 60 provided in the exhaust system 40.

As described above, the exhaust system 40 includes the annular baffle plate 41, the first pressure adjusting mechanism 42, the exhaust mechanism 43, and the second pressure adjusting mechanism 60.

The annular baffle plate 41 is disposed around the substrate support 11 in a plan view so as to separate the plasma processing space 10s and the exhaust path 10e from each other. The annular baffle plate 41 is an annular plate-shaped member having a large number of openings 41a, communicates the plasma processing space 10s with the exhaust path 10e through the openings 41a, and captures or reflects a plasma generated in the plasma processing space 10s to prevent leakage of the plasma to the exhaust path 10e. Further, the annular baffle plate 41 is disposed in parallel to the substrate W placed on the substrate support 11, and is disposed at a position lower than the upper surface of the substrate W, more specifically, the substrate support surface in the drawing. Thus, the annular baffle plate 41 is horizontally disposed so as to surround the sidewall of the substrate support 11, and has the plurality of openings 41a formed so as to vertically penetrate the annular baffle plate 41.

The first pressure adjusting mechanism 42 adjusts an operation of decompressing the plasma processing space 10s, that is, the internal pressure (decompression degree) of the plasma processing chamber 10 that is performed by the exhaust mechanism 43. As the first pressure adjusting mechanism 42, for example, a pressure control valve such as an adaptive pressure control (APC) valve or a poppet valve can be selected. Thus, the pressure control valve is configured to control the pressure within the plasma processing chamber, and is selected from at least one of an APC valve or a poppet valve.

The exhaust mechanism 43 decompresses the inside of the plasma processing space 10s. The exhaust mechanism 43 may include, for example, a vacuum pump such as a turbo molecular pump or a dry pump, or a combination thereof.

As described above, the second pressure adjusting mechanism 60 includes the upper plate 61, the movable structure 62, and the actuator 63.

For example, the upper plate (first annular plate) 61 is fixedly disposed with respect to a sidewall 11a of the substrate support 11 on the downstream side of the annular baffle plate 41 in the exhaust path 10e. Thus, the first annular plate 61 is disposed below the annular baffle plate 41. In one embodiment, the stationary upper annular plate 61 is fixed to the sidewall 11a of the substrate support 11, and extends horizontally outwardly from the sidewall 11a of the substrate support 11. Then, a first gap G1 is formed between the stationary upper annular plate 61 and the sidewall 102 of the plasma processing chamber 10. In one embodiment, a distance H1 between the annular baffle plate 41 and the stationary upper annular plate 61 is 40 mm or more. In one embodiment, the first annular plate 61 completely vertically overlaps the annular baffle plate 41. The upper plate 61 is an annular imperforate plate-shaped member having no opening and is formed such that a width L1 (see FIG. 3) of an annular portion is smaller than a width L3 (see FIG. 3) of the annular baffle plate 41. In other words, an exhaust flow path G1 having a width [L3−L1] is formed between an outer end of the upper plate 61 and the sidewall 102 of the plasma processing chamber 10. The width L1 of the upper plate 61 may be freely designed. At this time, it is preferable that the width [L3−L1] of the exhaust flow path G1 is smaller than at least the width L1 of the upper plate 61 (L3−L1<L1). In other words, the width L1 of the upper plate 61 is larger than a half width (L3/2) of the annular baffle plate 41. The width [L3−L1] of the exhaust flow path G1 is larger than a width of a gap C, which will be described later.

The distance H1 between the annular baffle plate 41 and the upper plate 61 (see FIG. 3) may also be freely designed. However, for example, from the viewpoint of appropriately adjusting the exhaust conductance, the distance H1 may be at least 40 mm or more.

For example, the movable structure 62 is disposed on the sidewall 102 side of the plasma processing chamber 10 on the downstream side of the upper plate 61 in the exhaust path 10e. Thus, the movable structure 62 is disposed below the stationary upper annular plate 61. In one embodiment, the movable structure 62 includes a cylindrical wall 62a and a lower plate 62b. The cylindrical wall 62a and the lower plate 62b may be separate members or may be integrated. The movable structure 62 has a substantially L-shaped cross-sectional shape formed by the cylindrical wall 62a and the lower plate 62b. Thus, in the following description, the movable structure 62 may be referred to as an L-shaped structure.

The cylindrical wall 62a is disposed vertically along the sidewall 102 of the plasma processing chamber 10, and is disposed to be slightly spaced apart from the sidewall 102 such that the gap C as a bypass flow path is formed between the cylindrical wall 62a and the sidewall 102. That is, the cylindrical wall 62a and the sidewall 102 of the plasma processing chamber 10 are concentrically disposed, and the cylindrical wall 62a has an outer diameter slightly smaller than an inner diameter of the sidewall 102. Thus, the annular gap C is formed between the sidewall 102 forming the inner wall surface of the plasma processing chamber 10 and the cylindrical wall 62a of the movable structure 62. In one embodiment, the cylindrical wall 62a is formed of a non-porous member having no opening, and extends vertically along the sidewall 102 of the plasma processing chamber 10. Then, a second gap G2 is formed between the cylindrical wall 62a and the sidewall 102 of the plasma processing chamber 10. In one embodiment, the cylindrical wall 62a has a vertical dimension H2 of 10 mm to 60 mm.

A width L4 of the gap C (second gap G2) (see FIG. 3) is a size by which the gap may constantly create an exhaust flow from the plasma processing space 10s by the exhaust mechanism 43 and does not affect the internal pressure of the plasma processing space 10s during a plasma processing, and is preferably 2.0 mm or less. In one embodiment, the annular gap C has the same width L4 over the entire circumference.

A length of the gap C, that is, the vertical length H2 of the cylindrical wall 62a (see FIG. 3) is determined in consideration of the width L4 of the gap C, and is preferably 10 mm to 60 mm. Specifically, the vertical length H2 of the cylindrical wall 62a is determined such that the conductance of exhaust performed by the exhaust mechanism 43 via the gap C (hereinafter, simply referred to as “exhaust conductance”) becomes a predetermined desired value. More specifically, the length H2 of the gap C is determined to be large when the width L4 of the gap C is large, and the length H2 of the gap C is determined to be small when the width L4 of the gap C is small such that the exhaust conductance becomes the desired value.

The lower plate (second annular plate) 62b is connected to the cylindrical wall 62a so as to protrude from the upper end of the cylindrical wall 62a near the inner wall (on a radial inner side surface) toward an inner circumferential side (that is, radial inner side) of the plasma processing chamber 10. For example, the lower plate 62b is disposed substantially parallel to the upper plate 61 on the downstream side of the upper plate 61 in the exhaust path 10e. Thus, the second annular plate 62b is disposed below the first annular plate 61. In one embodiment, the lower annular plate 62b extends horizontally inwardly from the upper end of the cylindrical wall 62a. The lower annular plate 62b has an annular overlapping portion 62c that vertically overlaps the stationary upper annular plate 61. Then, a third gap G3 is formed between the lower annular plate 62b and the sidewall 11a of the substrate support 11. In one embodiment, the first gap G1 is smaller than the width L1 of the stationary upper annular plate 61 and larger than the second gap G2. In one embodiment, the second annular plate 62b completely vertically overlaps the annular baffle plate 41. The lower plate 62b is an annular imperforate plate-shaped member having no opening, and is formed such that a width L2 of the movable structure 62 (see FIG. 3: a total value of the width of the annular portion of the lower plate 62b and the thickness of the cylindrical wall 62a) is smaller than the width L3 of the annular baffle plate 41. In other words, an exhaust flow path G3 having a width [L3−L2] is formed between the outer end of the lower plate 62b and the sidewall 102 of the plasma processing chamber 10. The width L2 of the lower plate 62b may be freely designed.

The first annular plate 61 and the second annular plate 62b do not have a plurality of openings vertically penetrating therethrough, unlike the annular baffle plate 41. Thus, each of the plurality of openings 41a in the annular baffle plate 41 is shielded by at least one of the first annular plate 61 and the second annular plate 62b (more specifically, the movable structure 62 including the cylindrical wall 62a) in a plan view. That is, each opening 41a in the annular baffle plate 41 may be selectively shielded by the first annular plate 61 or the second annular plate 62b in a plan view, or may be shielded by both the first annular plate 61 and the second annular plate 62b in a plan view. Thus, the space below the second annular plate 62b is invisible when viewed vertically from above the openings 41a.

In the present embodiment, for example, the movable structure 62 is configured to be movable in the perspective direction (vertical direction in the illustrated example) with respect to the upper plate 61 by an operation of the actuator 63. In other words, the movable structure 62 is configured such that a distance H3 between the lower plate 62b and the upper plate 61 (see FIG. 3) can be freely adjusted by the operation of the actuator 63. For example, the operation of the actuator 63 can be controlled by the controller 2. The adjustment range of the distance H3 can be freely designed, but it is preferable that the distance H3 may be adjustable at least between 5 mm and 50 mm from the viewpoint of appropriately controlling the pressure of the plasma processing space 10s. Thus, at least one actuator 63 is configured to vertically move only the movable structure 62 based on the pressure detected by the pressure detector 50. That is, at least one actuator 63 is configured to vertically move the movable structure 62 without moving the first annular plate 61. That is, the first annular plate 61 functions as a stationary annular plate, and the second annular plate 62b of the movable structure 62 functions as a movable annular plate. Thus, the distance H3 between the first annular plate 61 and the second annular plate 62b is changed.

Here, as illustrated in FIGS. 3 and 5, the upper plate 61 and the lower plate 62b according to the present embodiment are disposed to form an annular overlapping portion OV where at least parts thereof in the radial direction overlap with respect to the exhaust direction (vertical direction in the illustrated example) in the exhaust path 10e. In other words, the respective widths L1 and L2 of the upper plate 61 and the lower plate 62b are determined so as to form the annular overlapping portion OV illustrated in FIGS. 3 and 5 (L3<L1+L2). A width of the annular overlapping portion OV may be freely designed, and may be designed to be, for example, 5 mm to 10 mm. In one embodiment, the second annular plate 62b is disposed below the first annular plate 61 and has a second annular overlapping portion 62c. The second annular overlapping portion 62c vertically overlaps a part of the first annular plate 61 (that is, a first annular overlapping portion 61c). Thus, the annular overlapping portion OV of the upper plate 61 and the lower plate 62b is a portion where a part of the second annular plate 62b (that is, the second annular overlapping portion 62c) and a part of the first annular plate 61 (that is, the first annular overlapping portion 61c) vertically overlap each other.

At this time, a magnitude relationship between the width L1 of the upper plate 61 and the width L2 of the lower plate 62b is not particularly limited. For example, either the width L1 or the width L2 may be larger, or the width L1 and the width L2 may be the same. From the viewpoint of appropriately adjusting the exhaust conductance, it is preferable that the width L1 is larger than the width L2 (L1>L2).

The exhaust system 40 provided in the plasma processing apparatus 1 according to the present embodiment is configured as described above.

Here, during plasma processing performed by using a plasma processing apparatus in related art, it is required to perform the supply of a processing gas or the exhaust by the exhaust system with respect to the entire inside of the plasma processing chamber including the plasma processing space and the exhaust path, which results in a need for a great deal of time for the pressure control of the plasma processing chamber (plasma processing space).

In this respect, in the present embodiment, as described above, the upper plate 61 and the movable structure 62 (second pressure adjusting mechanism 60) forming the annular overlapping portion OV in at least a part thereof in the radial direction are disposed in the exhaust path 10e, and the lower plate 62b of the movable structure 62 is configured to be movable in the perspective direction with respect to the upper plate 61. The upper plate 61 and the lower plate 62b have no openings formed therein. Therefore, the upper plate 61 and the lower plate 62b function as a second pressure control valve by reducing the distance H3 illustrated in FIG. 3.

In other words, by reducing the distance H3 between the upper plate 61 and the lower plate 62b, the exhaust path 10e on the downstream side of the lower plate 62b is separated from the plasma processing space 10s, so that the volume of the plasma processing chamber 10 can be reduced likewise. Then, since the volume of the plasma processing chamber 10 is reduced in this way, the time required for the pressure control of the plasma processing space 10s can be shortened.

In the second pressure adjusting mechanism 60 according to the present embodiment, as described above, the lower plate 62b is configured to be movable in the perspective direction with respect to the upper plate 61. Thus, the amount of exhaust from the plasma processing space 10s by the exhaust mechanism 43 can be freely adjusted, so that the internal pressure of the plasma processing space 10s can be precisely controlled. That is, since the amount of exhaust from the plasma processing space 10s is changed according to the magnitude of the distance H3 between the upper plate 61 and the lower plate 62b, the internal pressure of the plasma processing space 10s can be appropriately controlled by adjusting the distance H3 based on, for example, the measurement result by the pressure detector 50.

Specifically, for example, when the internal pressure of the plasma processing space 10s is lower than a set pressure, the amount of exhaust is reduced by raising the lower plate 62b to reduce the distance H3, and therefore, the internal pressure of the plasma processing space 10s can be increased. For example, when the internal pressure of the plasma processing space 10s is higher than the set pressure, the amount of exhaust is increased by lowering the lower plate 62b to increase the distance H3, and therefore, the internal pressure of the plasma processing space 10s can be reduced.

At this time, in addition to the second pressure adjusting mechanism 60, the first pressure adjusting mechanism 42 disposed at the bottom of the plasma processing chamber 10 is used to adjust the exhaust from the plasma processing space 10s in two stages, whereby the internal pressure of the plasma processing space 10s can be controlled more precisely.

With the plasma processing apparatus 1 according to the present embodiment, in addition to the exhaust from the distance H3 between the upper plate 61 and the lower plate 62b, the minute constant exhaust of the plasma processing space 10s from the gap C formed between the cylindrical wall 62a of the movable structure 62 and the sidewall 102 of the plasma processing chamber 10 is performed.

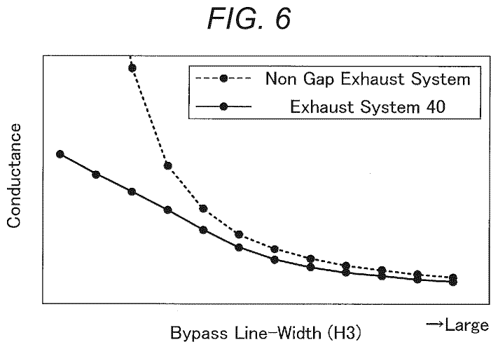

The present inventors have intensively studied and found that when no gap C is formed between the cylindrical wall 62a of the movable structure 62 and the sidewall 102 of the plasma processing chamber 10 and the exhaust of the plasma processing space 10s is performed only from the distance H3 between the upper plate 61 and the lower plate 62b, plasma processing on the substrate W may not be appropriately performed. Specifically, as illustrated in FIG. 6, it has been found that, particularly when the distance H3 between the upper plate 61 and the lower plate 62b is small, a change in internal pressure of the plasma processing space 10s (that is, value of the exhaust conductance in the example in FIG. 6) is increased (steeply increased), and plasma processing cannot be appropriately performed on the substrate W due to the pressure change.

In this respect, in the exhaust system 40 of the plasma processing apparatus 1 according to the present embodiment, by performing the minute constant exhaust of the plasma processing space 10s from the gap C, even when the distance H3 between the upper plate 61 and the lower plate 62b is reduced as illustrated in FIG. 6, a change in internal pressure can be prevented from being increased (steeply increased), and plasma processing on the substrate W can be appropriately performed.

Particularly, according to the present embodiment, the width L4 and the length H2 of the gap C are defined so as not to affect the internal pressure of the plasma processing space 10s during the plasma processing. Specifically, the preferred width L4 of the gap C is 2.0 mm or less as described above, and the preferred length H2 is 10 mm to 60 mm as described above. Accordingly, the internal pressure of the plasma processing space 10s can be prevented from being steeply changed by the constant exhaust from the gap C, and an appropriate plasma processing result can be obtained for the substrate W.

### Modification Examples

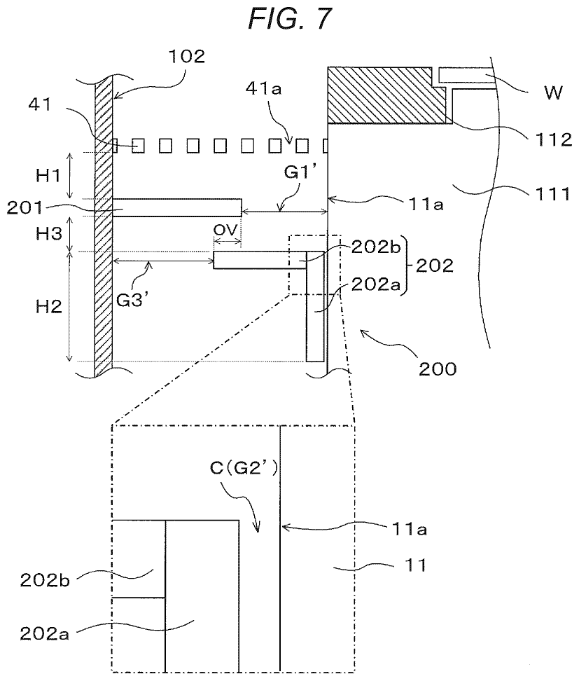

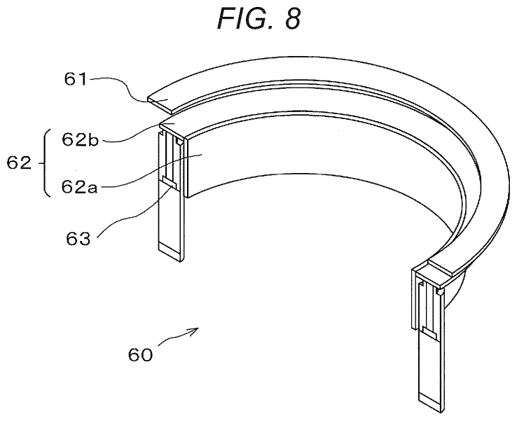

In the second pressure adjusting mechanism 60 in the embodiment described above, the upper plate 61 is disposed on the sidewall 11a side of the substrate support 11, and the movable structure 62 is disposed on the sidewall 102 side of the plasma processing chamber 10, but disposition of the upper plate 61 and the movable structure 62 is not limited to the embodiment described above. That is, for example, as in a second pressure adjusting mechanism 200 illustrated in FIGS. 7 and 8, the upper plate 201 may be fixedly disposed on the sidewall 102 side of the plasma processing chamber 10, and a movable structure 202 may be disposed on the sidewall 11a side of the substrate support 11. In this case, the gap C for performing constant ventilation of the plasma processing space 10s is formed between a cylindrical wall 202a of the movable structure 202 and the sidewall 11a of the substrate support 11. In other words, a lower plate 202b of the movable structure 202 is integrally provided with the cylindrical wall 202a so as to protrude from an upper end of the cylindrical wall 202a near an outer wall (on a radial outer side surface) toward an outer circumferential side (that is, a radial outer side) of the plasma processing chamber 10. That is, in the example illustrated in FIGS. 7 and 8, the stationary upper annular plate 201 is fixed to the sidewall 102 of the plasma processing chamber 10, and extends horizontally inwardly from the sidewall 102 of the plasma processing chamber 10. Then, a first gap G1′ is formed between the stationary upper annular plate 201 and the sidewall 11a of the substrate support 11. The movable structure 202 is disposed below the stationary upper annular plate 201. The movable structure 202 includes the cylindrical wall 202a and the lower annular plate 202b, which may be separate members or may be integrated together. The cylindrical wall 202a extends vertically along the sidewall 11a of the substrate support 11. Then, a second gap G2′ is formed between the cylindrical wall 202a and the sidewall 11a of the substrate support 11. The lower annular plate 202b extends horizontally outwardly from the upper end of the cylindrical wall 202a. The lower annular plate 202b has the annular overlapping portion OV that vertically overlaps the stationary upper annular plate 201 (i.e., the annular overlapping portion OV represents overlapping portions of the stationary upper annular plate 201 and the lower annular plate 202b). Then, a third gap G3′ is formed between the lower annular plate 202b and the sidewall 102 of the plasma processing chamber 10. An actuator is configured to move the movable structure 202 vertically. The stationary upper annular plate 201 and the lower annular plate 202b are an annular imperforate plate-shaped member having no openings.

Even in such a case, by adjusting the distance H3 between the upper plate 201 and the lower plate 202b based on a measurement result by the pressure detector 50, the internal pressure of the plasma processing space 10s can be precisely controlled, and a time required for the pressure control can be appropriately shortened. Thus, the first annular plate 201 may be fixed to the sidewall 102 of the plasma processing chamber 10, and in this case, the movable structure 202 is disposed on or near the sidewall 11a of the substrate support 11.

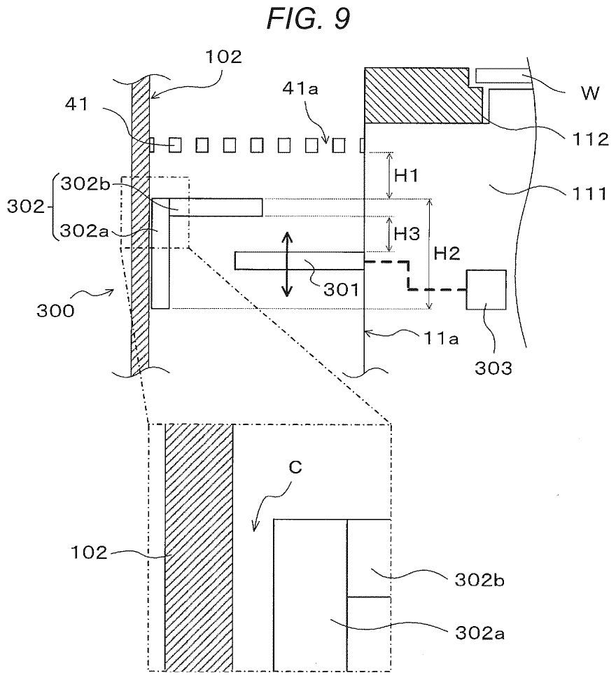

In the second pressure adjusting mechanism 60 in the embodiment described above, the upper plate 61 is disposed below the annular baffle plate 41, and the movable structure 62 is disposed below the upper plate 61, but disposition of the upper plate 61 and the movable structure 62 is not limited to the embodiment described above. That is, for example, as in a second pressure adjusting mechanism 300 illustrated in FIG. 9, an L-shaped structure 302 having a substantially L shape may be fixedly disposed below the annular baffle plate 41, and a movable lower plate 301 may be disposed below an upper plate 302b of the L-shaped structure 302. In this case, the L-shaped structure 302 includes a cylindrical wall 302a disposed along the sidewall 102 of the plasma processing chamber 10, and the upper plate 302b integrally provided with the cylindrical wall 302a to protrude from the upper end of the cylindrical wall 302a near the inner wall toward the inner circumferential side of the plasma processing chamber 10. In this case, the gap C for performing the constant ventilation of the plasma processing space 10s is formed between the cylindrical wall 302a of the L-shaped structure 302 and the sidewall 102 of the plasma processing chamber 10. Further, in this case, the L-shaped structure 302 is fixedly disposed near the sidewall 102 of the plasma processing chamber 10, and the movable lower plate 301 is fixedly disposed on the sidewall 11a of the substrate support 11. The movable lower plate 301 is configured to be movable in the perspective direction with respect to the upper plate 302b by an actuator 303.

Even in such a case, by adjusting the distance H3 between the upper plate 302b and the movable lower plate 301 based on the measurement result by the pressure detector 50, the internal pressure of the plasma processing space 10s can be precisely controlled, and the time required for the pressure control can be appropriately shortened. Thus, the L-shaped structure 302 may be fixed near the sidewall 102 of the plasma processing chamber 10, and in this case, the first annular plate 301 is disposed below the L-shaped structure 302 and on or near the sidewall 11a of the substrate support 11 so as to be freely movable vertically.

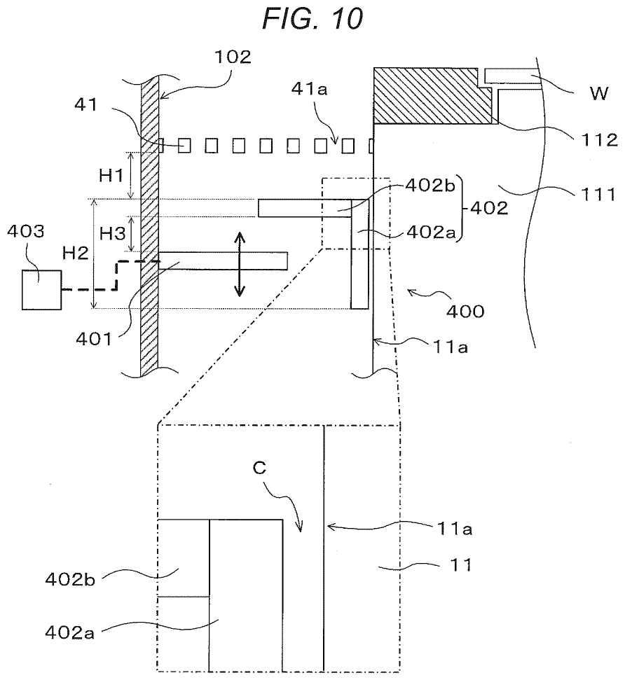

In the second pressure adjusting mechanism 300 illustrated in FIG. 9, the L-shaped structure 302 is disposed on the sidewall 102 side of the plasma processing chamber 10, and the movable lower plate 301 is disposed on the sidewall 11a side of the substrate support 11, but disposition of the L-shaped structure 302 and the movable lower plate 301 is not limited to the above-described embodiment. That is, for example, as in a second pressure adjusting mechanism 400 illustrated in FIG. 10, an L-shaped structure 402 having a substantially L shape may be disposed on the sidewall 11a side of the substrate support 11, and a movable lower plate 401 may be disposed on the sidewall 102 side of the plasma processing chamber 10. In this case, the gap C for performing the constant ventilation of the plasma processing space 10s is formed between a cylindrical wall 402a of the L-shaped structure 402 and the sidewall 11a of the substrate support 11.

Even in such a case, by adjusting the distance H3 between an upper plate 402b and the movable lower plate 401 based on the measurement result by the pressure detector 50, the internal pressure of the plasma processing space 10s can be precisely controlled, and the time required for the pressure control can be appropriately shortened. Thus, the L-shaped structure 402 may be fixed near the sidewall 11a of the substrate support 11, and in this case, the first annular plate 401 is disposed on or near the sidewall 102 of the plasma processing chamber 10 so as to be freely movable vertically.

In the above-described embodiment, the exhaust system has been configured such that the position of the upper plate 61 is fixed with respect to the position of the annular baffle plate 41 and the lower plate 62b may be moved in the perspective direction (vertical direction) with respect to the position of the upper plate 61, but a configuration of the exhaust system is not limited thereto. That is, although not illustrated, the exhaust system may be configured such that the lower plate 62b is fixed with respect to the position of the annular baffle plate 41 and the upper plate 61 (movable structure 62) may be moved between the annular baffle plate 41 and the lower plate 62b. In other words, the upper plate 61 (movable structure 62) may be configured to be movable in the perspective direction with respect to the lower plate 62b. Thus, at least one actuator 63 is configured to vertically move only the first annular plate 61 based on the pressure detected by the pressure detector 50. That is, the at least one actuator 63 is configured to vertically move the first annular plate 61 without moving the L-shaped structure. Thus, the distance H3 between the first annular plate 61 and the second annular plate 62b is changed. Even in this case, by adjusting the distance H3 between the upper plate 61 and the lower plate 62b based on the measurement result by the pressure detector 50, the internal pressure of the plasma processing space 10s can be precisely controlled, and a time required for the pressure control can be appropriately shortened.

Further, both the upper plate (first annular plate) 61 and the lower plate 62b (movable structure 62) may be configured to be movable in the perspective direction (vertical direction). Thus, at least one actuator 63 is configured to vertically move the upper plate 61 and the second annular plate 62b based on the pressure detected by the pressure detector 50. Thus, the distance H3 between the first annular plate 61 and the second annular plate 62b is changed. Even in this case, by adjusting the distance H3 between the upper plate 61 and the lower plate 62b based on the measurement result by the pressure detector 50, the internal pressure of the plasma processing space 10s can be precisely controlled, and a time required for the pressure control can be appropriately shortened.

The structure for vertically moving the upper plate 61 in place of or in addition to the substantially L-shaped movable structure 62 is not limited to the second pressure adjusting mechanism 60 described above, but can also be similarly applied to the second pressure adjusting mechanisms 200, 300, and 400 illustrated in FIGS. 7 to 10. Thus, in any of the second pressure adjusting mechanisms 60, 200, 300, and 400, the distance H3 between the first annular plate and the second annular plate can be freely adjusted by the operation of at least one actuator. Thus, the plasma processing apparatus according to the embodiment includes the first annular plate disposed below the annular baffle plate, the second annular plate disposed to vertically overlap a part of the first annular plate, the cylindrical wall vertically disposed along the sidewall of the plasma processing chamber or the sidewall of the substrate support from the radial end of either the first annular plate or the second annular plate, a gap being formed between the cylindrical wall and the sidewall of the plasma processing chamber or the sidewall of the substrate support, and at least one actuator relatively vertically moving at least one of the first annular plate and the second annular plate.

### <Plasma Processing Method>

Next, a plasma processing method using the plasma processing system configured as described above will be described. In the following description, an example will be described in which the plasma processing apparatus 1 includes the second pressure adjusting mechanism 60 illustrated in FIGS. 3 and 4. In the plasma processing apparatus 1, the substrate W is subjected to any plasma processing such as etching processing, film forming processing, and diffusion processing.

In the plasma processing method, first, the substrate W is transferred into the plasma processing chamber 10, and the substrate W is placed on the substrate support 11. Thereafter, by supplying a direct-current voltage to an electrode in the electrostatic chuck, the substrate W is adsorbed and held by the electrostatic chuck by a coulomb force. After the substrate W is transferred into the plasma processing chamber 10, the inside of the plasma processing chamber 10 is decompressed to a desired degree of vacuum by the exhaust system 40.

Next, a processing gas is supplied from the gas supply 20 to the plasma processing space 10s via the center gas injector 13. A radio-frequency power HF for plasma generation is supplied to the antenna 14 by the first RF generator 31a, and a plasma is generated from the processing gas in the plasma processing space 10s. Then, desired plasma processing is performed on the substrate W on the substrate support 11 by the action of the generated plasma. That is, the plasma processing is performed on the substrate W by exposing the substrate W to the generated plasma. The internal pressure of the plasma processing chamber 10 during the plasma processing is measured (detected) over time by the pressure detector 50.

Here, the internal pressure of the plasma processing chamber 10 is adjusted to a desired set pressure by supplying the processing gas into the plasma processing space 10s. At this time, since the upper plate 61 and the lower plate 62b act as the second pressure adjusting valve by reducing the distance H3 between the upper plate 61 and the lower plate 62b as described above, the volume of the plasma processing chamber 10 may be reduced in a pseudo manner, whereby the internal pressure of the plasma processing chamber 10 can be controlled in a short time.

Further, at this time, the constant exhaust of the plasma processing space 10s is performed through the gap C formed between the cylindrical wall 62a of the movable structure 62 and the sidewall 102 of the plasma processing chamber 10 as described above. Accordingly, even when the distance H3 between the upper plate 61 and the lower plate 62b is reduced, the internal pressure of the plasma processing chamber 10 can be prevented from being steeply changed.

As described above, in the plasma processing apparatus 1, it is important to precisely control the internal pressure of the plasma processing chamber 10 in order to appropriately perform the plasma processing on the substrate W. Therefore, in the present embodiment, the distance H3 between the upper plate 61 and the lower plate 62b in the exhaust system 40 is controlled based on the internal pressure of the plasma processing chamber 10 measured by the pressure detector 50. Specifically, when the measurement result by the pressure detector 50 is lower than the set pressure of the plasma processing, the internal pressure of the plasma processing chamber 10 is raised by raising the lower plate 62b to reduce the distance H3. When the measurement result by the pressure detector 50 is higher than the set pressure in the plasma processing, the internal pressure of the plasma processing chamber 10 is lowered by lowering the lower plate 62b to increase the distance H3. Thus, the controller 2 compares the pressure detected by the pressure detector 50 with a predetermined set pressure to determine whether the detected pressure is higher and/or lower than the set pressure. The controller 2 controls at least one actuator 63 such that the distance H3 increases when the detected pressure is higher than the set pressure, and the distance H3 decreases when the detected pressure is lower than the set pressure. For example, in the example in FIG. 3, the controller 2 lowers the movable structure 62 when the detected pressure is higher than the set pressure, and raises the movable structure 62 when the detected pressure is lower than the set pressure.

Once the plasma processing for the substrate W is completed, the supply of the radio-frequency power HF and the radio-frequency power LF from the RF power source 31 and the supply of the processing gas by the gas supply 20 are stopped. In a case where the radio-frequency power LF has been supplied during the plasma processing, the supply of the radio-frequency power LF is also stopped. Next, the processing gas is exhausted from the inside of the plasma processing chamber 10 by the exhaust system 40. Next, the supply of the heat transfer gas to the rear surface of the substrate W is stopped, and the adsorption and holding of the substrate W by the electrostatic chuck is stopped.

The substrate W subjected to the plasma processing is then transferred from the plasma processing chamber 10 to an external apparatus such as a transfer chamber by a substrate transfer mechanism (not illustrated), and a series of the plasma processing on the substrate W is completed.

In the plasma processing according to the embodiment described above, the lower plate 62b is appropriately moved based on the internal pressure of the plasma processing chamber 10 detected by the pressure detector 50 during the plasma processing, but a method of controlling the lower plate 62b is not limited thereto. For example, instead of feedback-controlling an operation of the lower plate 62b based on the internal pressure measured by the pressure detector 50 in the middle of the plasma processing, the distance H3 may be changed for each process based on set pressures of various processes which are predetermined before the start of the plasma processing.

It shall be understood that the embodiments disclosed herein are illustrative and are not restrictive in all aspects. The embodiment described above may be omitted, replaced, or modified in various forms without departing from the scope and spirit of the appended claims.

For example, in the above-described embodiments, a case where the plasma processing apparatus 1 includes an inductively coupled plasma generator has been described as an example, but a configuration of the plasma generator is not limited thereto. That is, the time require for the pressure control may be appropriately shortened by applying the technique of the present disclosure to various plasma processing apparatuses that are required to shorten the time required for the pressure control.

### Example

Hereinafter, an example of the technique according to the present disclosure will be described, but the present technique is not limited to the following example.

A time required for controlling the internal pressure of the plasma processing chamber 10 was measured by the present inventors in a case where the distance H3 is reduced by the above-described second pressure adjusting mechanism 60 to reduce in a pseudo manner the volume of the plasma processing chamber 10 (Example) and in a case where the second pressure adjusting mechanism 60 is not included and the volume of the exhaust path 10e is included in the volume of the plasma processing chamber 10 (Comparative Example).

Specifically, in each case of Example and Comparative Example, the processing gas was supplied to the plasma processing space 10s, and the time until the internal pressure of the plasma processing chamber 10 is raised to a desired set pressure was measured.

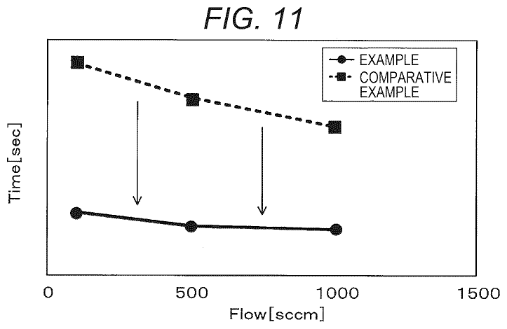

FIG. 11 is a diagram schematically illustrating the result of the present Example, and is a graph illustrating a relationship between a flow rate (horizontal axis) of the processing gas supplied to the plasma processing chamber 10 and a time (vertical axis) required to reach the set pressure. In the present Example, the set pressure was 100 mT, and a supply flow rate of the processing gas was 100 sccm, 500 sccm, and 1000 sccm. In the drawings, the solid line represents Example, and the broken line represents Comparative Example.

As illustrated in FIG. 11, it can be seen that the time required for the internal pressure to reach the set pressure is shortened by controlling the internal pressure of the plasma processing chamber 10 while reducing the distance H3 between the upper plate 61 and the lower plate 62b. Specifically, as a result of studies by the present inventors, it could be found that the time required to reach the set pressure in the Example can be reduced to about 30% to 40% compared to a case where the second pressure adjusting mechanism 60 is not included.

At this time, it was confirmed that a change in the internal pressure of the plasma processing chamber 10 can be made gentle by performing constant exhaust through the gap C formed between the cylindrical wall 62a and the sidewall 102 of the plasma processing chamber 10.

As can be seen from the above results, by providing the upper plate 61 and the movable structure 62 acting as the second pressure adjusting valve in the plasma processing apparatus 1, the time required for the pressure control of the plasma processing chamber 10 can be appropriately shortened. At the same time, the change in the internal pressure of the plasma processing chamber 10 can be made gentle (the change in internal pressure can be prevented from being steeply increased), so that appropriate plasma processing results can be obtained for the substrate W. The present invention encompasses various modifications to each of the examples and embodiments discussed herein. According to the invention, one or more features described above in one embodiment or example can be equally applied to another embodiment or example described above. The features of one or more embodiments or examples described above can be combined into each of the embodiments or examples described above. Any full or partial combination of one or more embodiment or examples of the invention is also part of the invention.

1. A plasma processing apparatus comprising:
a plasma processing chamber;
a substrate support disposed in the plasma processing chamber;
an annular baffle plate disposed to surround the substrate support, the annular baffle plate having openings;
a stationary upper annular plate disposed below the annular baffle plate and extending outwardly from a sidewall of the substrate support, a first gap being formed between the stationary upper annular plate and a sidewall of the plasma processing chamber;
a movable structure disposed below the stationary upper annular plate, the movable structure including:
a cylindrical wall vertically extending along the sidewall of the plasma processing chamber, a second gap being formed between the cylindrical wall and the sidewall of the plasma processing chamber; and
a lower annular plate extending inwardly from an upper end of the cylindrical wall, the lower annular plate having an annular overlapping portion vertically overlapping the stationary upper annular plate, a third gap being formed between the lower annular plate and the sidewall of the substrate support; and
an actuator configured to vertically move the movable structure.

2. The plasma processing apparatus according to claim 1, further comprising:
a pressure detector configured to detect a pressure in the plasma processing chamber; and
controller circuitry configured to control, based on the detected pressure, the actuator such that a distance between the stationary upper annular plate and the movable structure is changed.

3. The plasma processing apparatus according to claim 2, wherein
the controller circuitry
controls the actuator such that the distance between the stationary upper annular plate and the movable structure increases when the detected pressure is higher than a set pressure, and
controls the actuator such that the distance between the stationary upper annular plate and the movable structure decreases when the detected pressure is lower than the set pressure.

4. The plasma processing apparatus according to claim 1, wherein
the second gap is 2.0 mm or less.

5. The plasma processing apparatus according to claim 4, wherein
the annular overlapping portion has a width of 5 mm to 10 mm.

6. The plasma processing apparatus according to claim 5, wherein
the first gap is smaller than a width of the stationary upper annular plate and larger than the second gap.

7. The plasma processing apparatus according to claim 6, wherein
a distance between the annular baffle plate and the stationary upper annular plate is 40 mm or more.

8. The plasma processing apparatus according to claim 4, wherein
the cylindrical wall has a vertical dimension of 10 mm to 60 mm.

9. The plasma processing apparatus according to claim 4, wherein
a width of the stationary upper annular plate is larger than a width of the lower annular plate.

10. The plasma processing apparatus according to claim 4, wherein
the plasma processing chamber has a volume of 50 L or more.

11. The plasma processing apparatus according to claim 10, further comprising:
a pressure control valve configured to control the pressure in the plasma processing chamber, wherein
the pressure control valve is selected from at least one of an adaptive pressure control (APC) valve or a poppet valve.

12. A plasma processing apparatus comprising:
a plasma processing chamber;
a substrate support disposed in the plasma processing chamber;
an annular baffle plate disposed to surround the substrate support, the annular baffle plate having openings;
a stationary upper annular plate disposed below the annular baffle plate and extending inwardly from a sidewall of the plasma processing chamber, a first gap being formed between the stationary upper annular plate and a sidewall of the substrate support;
a movable structure disposed below the stationary upper annular plate, the movable structure including:
a cylindrical wall vertically extending along the sidewall of the substrate support, a second gap being formed between the cylindrical wall and the sidewall of the substrate support; and
a lower annular plate extending outwardly from an upper end of the cylindrical wall, the lower annular plate having an annular overlapping portion vertically overlapping the stationary upper annular plate, a third gap being formed between the lower annular plate and the sidewall of the plasma processing chamber; and
an actuator configured to vertically move the movable structure.

13. The plasma processing apparatus according to claim 12, further comprising:
a pressure detector configured to detect a pressure in the plasma processing chamber; and
controller circuitry configured to control, based on the detected pressure, the actuator such that a distance between the stationary upper annular plate and the movable structure is changed.

14. The plasma processing apparatus according to claim 13, wherein
the controller circuitry:
controls the actuator such that the distance between the stationary upper annular plate and the movable structure increases when the detected pressure is higher than a set pressure, and
controls the actuator such that the distance between the stationary upper annular plate and the movable structure decreases when the detected pressure is lower than the set pressure.

15. The plasma processing apparatus according to claim 12, wherein
the second gap is 2.0 mm or less.

16. The plasma processing apparatus according to claim 15, wherein
the annular overlapping portion has a width of 5 mm to 10 mm.

17. The plasma processing apparatus according to claim 15, wherein
the cylindrical wall has a vertical dimension of 10 mm to 60 mm.

18. A plasma processing apparatus comprising:
a plasma processing chamber;
a substrate support disposed in the plasma processing chamber;
an annular baffle plate disposed to surround the substrate support, the annular baffle plate having openings;
a first annular plate disposed below the annular baffle plate and extending outwardly from a sidewall of the substrate support, a first gap being formed between the first annular plate and a sidewall of the plasma processing chamber;
a structure disposed below the first annular plate, the structure including:
a cylindrical wall vertically extending along the sidewall of the plasma processing chamber, a second gap being formed between the cylindrical wall and the sidewall of the plasma processing chamber; and
a second annular plate extending inwardly from an upper end of the cylindrical wall, the second annular plate having an annular overlapping portion vertically overlapping the first annular plate, a third gap being formed between the second annular plate and the sidewall of the substrate support; and
at least one actuator configured to vertically move at least one of the first annular plate and the structure.

19. A plasma processing apparatus comprising:
a plasma processing chamber;
a substrate support disposed in the plasma processing chamber;
an annular baffle plate disposed to surround the substrate support, the annular baffle plate having openings;
a first annular plate disposed below the annular baffle plate;
a second annular plate disposed to vertically overlap a part of the first annular plate;
a cylindrical wall vertically disposed along a sidewall of the plasma processing chamber or a sidewall of the substrate support from a radial end of either the first annular plate or the second annular plate, a gap of 2.0 mm or less being formed between the cylindrical wall and the sidewall of the plasma processing chamber or the sidewall of the substrate support; and
at least one actuator configured to relatively vertically move at least one of the first annular plate and the second annular plate.

20. A plasma processing method using a plasma processing apparatus, the plasma processing apparatus including:
a plasma processing chamber;
a substrate support disposed in the plasma processing chamber;
an annular baffle plate disposed to surround the substrate support, the annular baffle plate having openings;
a first annular plate disposed below the annular baffle plate with an inner end fixed to a sidewall of the substrate support;
a movable structure disposed below the first annular plate, the movable structure including:
a cylindrical wall vertically disposed along a sidewall of the plasma processing chamber, a gap being formed between the cylindrical wall and the sidewall of the plasma processing chamber; and
a second annular plate disposed on an upper end of an inner wall of the cylindrical wall, the second annular plate having an annular overlapping portion vertically overlapping a part of the first annular plate;
an actuator; and
a pressure detector configured to detect a pressure in the plasma processing chamber; the method comprising:
(a) performing plasma processing on a substrate supported by the substrate support;
(b) detecting, by the pressure detector, the pressure in the plasma processing chamber; and
(c) vertically moving, by the actuator, the movable structure with respect to the first annular plate based on the detected pressure.
